(19) United States
(12) Patent Application Publication
(10) Pub. No.: US 2025/0053696 A1
(43) Pub. Date: Feb. 13, 2025

(54) BUILDING MANAGEMENT DESIGN SYSTEM USING SPACE MODELING

(71) Applicant: Ripple Engineering Corporation, Dover, DE (US)

(72) Inventor: Kevin Lawson, Brentwood, MO (US)

(73) Assignee: Ripple Engineering Corporation, Dover, DE (US)

(21) Appl. No.: 18/798,076

(22) Filed: Aug. 8, 2024

Related U.S. Application Data
(60) Provisional application No. 63/531,424, filed on Aug. 8, 2023.

(51) Int. Cl. G06F 30/13; G06F 30/18

(52) U.S. Cl. CPC G06F 30/13; G06F 30/18

(57) ABSTRACT

A system includes one or more processing circuits and memory storing instructions which, when executed, cause the one or more processing circuits to receive a building dataset comprising an architectural drawing of a building and metadata, model the building dataset by generating building properties of a building space based on the building dataset, determining building equipment based on the building properties and the building dataset, and generating, in a graphical representation of the building displayed on a user device, a space placement block of the building equipment, wherein the space placement block is an interactive graphical representation of the building equipment that is modifiable within the graphical representation of the building, and remodel, based on a modification of the space placement block, the building dataset by updating at least one of the building properties or building equipment to encode the modification of the space placement block into the building dataset.

### CROSS-REFERENCE TO RELATED PATENT APPLICATIONS

This application claims the benefit of and priority to U.S. Provisional Patent Application No. 63/531,424, filed Aug. 8, 2023, the entire disclosure of which is hereby incorporated by reference herein in its entirety and for all purposes.

### FIELD

The present disclosure relates generally to the field of designing engineering systems for building designs. More specifically, the present disclosure is directed to utilizing a digital building design to automatically produce engineering designs and provide a tangible output to the building designer.

### BACKGROUND

Generally, when a building designer needs to operationalize an architectural drawing, the building equipment and equipment infrastructure must be determined and modeled. The builder designer will send an architectural drawing to an engineer to determine necessary building equipment (e.g., electrical, structural, etc.), the equipment infrastructure to support the equipment (e.g., HVAC units, electrical conduits, etc.), and the logistics to install the building equipment and equipment infrastructure (e.g., costs, labor, etc.). This manual activity requires human intervention and prolonged periods of time. Furthermore, any modifications to the architectural drawings or engineering designs often result in the engineers spending a significant amount of time and money redesigning the building equipment and equipment infrastructure, and recalculating the costs and time to install such equipment.

### SUMMARY

One embodiment relates to a system. The system includes one or more processing circuits and memory storing instructions which, when executed, cause the one or more processing circuits to receive a building dataset comprising an architectural drawing of a building and metadata. The one or more processing circuits are also caused to model the building dataset by generating building properties of a building space based on the building dataset. The one or more processing circuits are also caused to determine building equipment based on the building properties and the building dataset. The one or more processing circuits are also caused to generate, in a graphical representation of the building displayed on a user device, a space placement block of the building equipment, where the space placement block is an interactive graphical representation of the building equipment that is modifiable within the graphical representation of the building. The one or more processing circuits are also caused to remodel, based on a modification of the space placement block, the building dataset by updating at least one of the building properties or building equipment to encode the modification of the space placement block into the building dataset.

One embodiment relates to a method. The method includes receiving a building dataset including an architectural drawing of a building and metadata. The method also includes generating building properties of a building space based on the metadata of the building dataset. The method also includes determining building equipment based on the building properties and the building dataset. The method also includes generating, in a graphical representation of the building, a space placement block of the building equipment, wherein the space placement block is an interactive graphical representation of the building equipment that is modifiable within the graphical representation of the building. The method also includes, in response to a modification of the space placement block, remodeling the building dataset by updating at least one of the building properties or building equipment to encode the modification of the space placement block into the building dataset.

Another embodiment relates to a method. The method includes receiving a building dataset including an architectural drawing of a building and space type data that represents a space type. The method also includes generating space properties data of the building based on the space type of a building space within the building, wherein the space properties data is retrieved from a space type dataset that includes a plurality of space type data and a plurality of space properties data associated with each space type. The method also includes determining a HVAC system and HVAC infrastructure from an equipment dataset, where the equipment dataset includes a plurality of HVAC systems and a plurality of HVAC infrastructures. The method also includes generating, in a graphical representation of the architectural drawing, a space placement block of the HVAC system and HVAC infrastructure, where the space placement block is an interactive graphical representation of the HVAC system and HVAC infrastructure that is modifiable within the graphical representation of the architectural drawing. The method also includes, based on a modification of the space placement block, remodeling the building dataset by updating at least one of the space properties data, HVAC system, or HVAC infrastructure to encode the modification of the space placement block into the building dataset.

### BRIEF DESCRIPTION OF THE DRAWINGS

FIG. 1 is a block diagram of a network-based computing system for an engineering design system, according to an example embodiment.

FIG. 2 is a block diagram of the user device, according to an example embodiment.

FIG. 3 is a flow diagram of a method of automatically producing an engineering design based on a building dataset, according to an example embodiment.

FIG. 4A is a display of a graphical representation of a building design displayed on the user device, according to an example embodiment.

FIG. 4B is a display of a graphical representation of a building design displayed on the user device depicting a space placement block of a HVAC unit on a ground level, according to an example embodiment.

FIG. 4C is a display of a graphical representation of a building design displayed on the user device depicting the space placement block of the HVAC unit on the ground level with building equipment, according to an example embodiment.

FIG. 4D is a display of a graphical representation of a building design displayed on the user device depicting a space placement block of the HVAC unit on a rooftop, according to an example embodiment.

FIG. 4E is a display of a graphical representation of a building design displayed on the user device depicting the space placement block of the HVAC unit on the rooftop with building equipment, according to an example embodiment.

FIG. 5 is a display of an interactive user interface on the user device to enable the user to configure the engineering design system, according to an example embodiment.

FIG. 6 is a display of an interactive user interface on the user device to enable the user to select building materials for components of the building design, according to an example embodiment.

FIG. 7 is a display of an interactive user interface of the user device displaying a mechanical model associated with the building design, according to an example embodiment.

### DETAILED DESCRIPTION

Referring to the figures generally, systems and methods of producing an engineering design based on a building dataset are described. In some embodiments, a user can input a building dataset via a user device (e.g., personal computing devices such as laptops, smartphones, tablet computing devices). The user device can transmit the building dataset to an engineering design system. In some embodiments, the engineering design system can initiate the modeling of the building dataset. In some embodiments, the engineering design system can analyze, collect, and/or access building properties (e.g., thermal properties, ventilation load, electrical load, etc.) from an engineering design database or other data sources. The engineering design system can then determine an engineering design (e.g., building equipment, building equipment infrastructure, and logistics) using building properties and/or other information (e.g., environmental, building codes, user preferences). After determining an engineering design, the engineering design system can transmit the engineering design to one or more user devices. The user devices can receive and/or generate graphical representations of the building design and engineering design. In some embodiments, the user can modify or update the graphical representation of the building dataset and engineering design via the user device. In response, the user device can transmit a modified building dataset and modified engineering design to the engineering design system to remodel the modified building dataset and the modified engineering design.

In general, the engineering design system can employ an improved heuristic in the generation, management, and adjustment of building and engineering design data. In some embodiments, the system can implement a building and space interpreter, providing improved adaptability and modelling, specifically when a building design lacks certain information necessary for the design of an optimal engineering system. In particular, the building and space interpreter can identify and determine additional building information based on existing metadata and discernible architect's intentions. In some embodiments, the systems and methods implement an improved model to design HVAC systems and structural floor loading based on space usage characteristics, building data, and user customizations. Additionally, the systems and methods can allow real-time, instantaneous feedback and corrections by users that can be used to remodel and design the HVAC systems and structural floor loading. In one example, the system could be used by an architect who needs information on the HVAC system for a planned structure. The architect could input their digital building design, and the system could then analyze this design and create a suitable HVAC system and structure. In this example, the system could then provide building design outputs, such as the requirement for a 3 feet (ft) by 3 feet closet to house the HVAC system, an estimated cost of $15,000, and an expected three-month lead time for ordering. As such, the detailed model could not only aid the architect in determining the spatial and functional aspects of the design but also assist in the planning of budget and schedule.

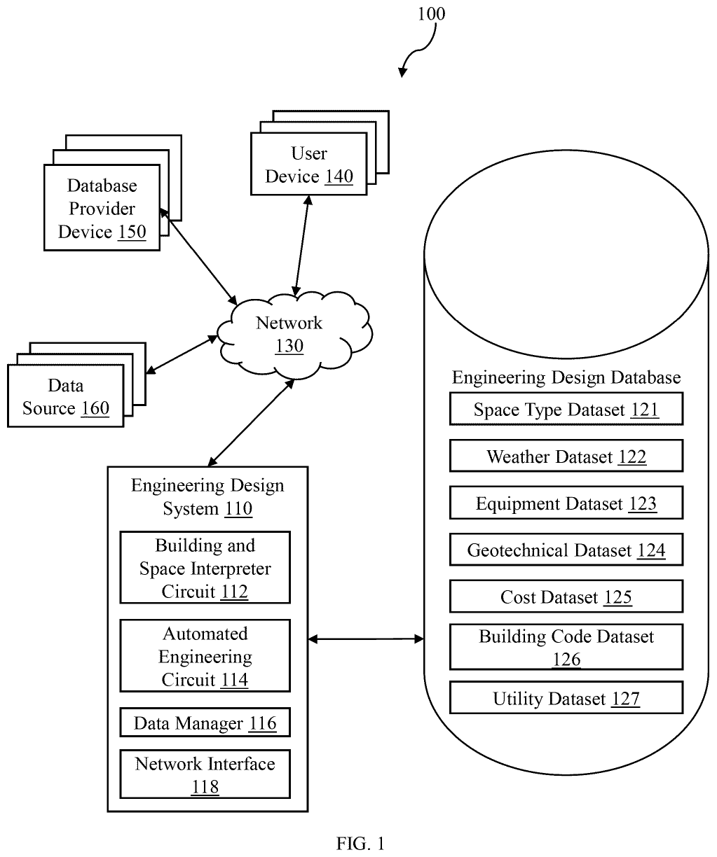

Referring to FIG. 1, a block diagram of a computing system 100 for an engineering design system 110 is shown according to an example embodiment. Generally, the engineering design system 110 and a user device 140 provide automated engineering designs and modeling of building infrastructure systems (e.g., HVAC system, structural systems, electrical systems, plumbing systems, etc.). In some embodiments, the building infrastructure systems can include building equipment and equipment infrastructure. In some embodiments, to use the engineering design system 110, a user, such as a building designer or an architect, can transmit a building dataset from a user device 140 to the engineering design system 110. In some embodiments, the engineering design system 110 can initiate the modeling of the building dataset. To determine engineering designs and logistic calculations, the engineering design system 110 can analyze, collect, and/or access building properties (e.g., thermal properties, equipment specifications, etc.) from an engineering design database 120. In some embodiments, the engineering design database 120 can store various engineering datasets and building metadata. In various embodiments, the engineering design database 120 can be configured to access, collect, and identify the data stored in the datasets from data sources 160 (e.g., Internet, internal server, hard drives, etc.). Accordingly, the engineering design database 120 can be configured to be updated in real-time (or near real-time) such that it allows the engineering design system 110 to retrieve building and equipment information in response to a request (e.g., by a user or from a circuit). As described in further detail below, the engineer design system 110 allows a user to automate engineering designs and modeling of building equipment and equipment infrastructure based on inputting a building dataset.

The engineering design system 110, is a computer system that can support the automation of engineering designs and modeling of building equipment and equipment infrastructure. Accordingly, in some embodiments, the engineering design system 110 can include a building and space interpreter circuit 112, an automated engineering circuit 114, a data manager 116, and a network interface 118.

Describing the engineering design system 110, in some embodiments, the building and space interpreter circuit 112 initiates the modeling of a building dataset. The building and space interpreter circuit 112 can be structured to analyze, collect, generate, and/or access building properties based on a user-inputted building dataset, which can include architectural drawings and metadata. For example, if the thermal properties of the building materials are not included in the building dataset, the building and space interpreter circuit 112 can query the engineering design database 120 for climate zone information based on location data in the metadata. In some embodiments, the building and space interpreter circuit 112 can query for the required thermal properties, as required by local codes and the climate zone, in the engineering design database 120 or other data sources. In some embodiments of the building and space interpreter circuit 112, for example, if the user inputs a building dataset with a building space labelled as “Conference Room,” the building and space interpreter circuit 112 can analyze, collect, generate, and/or access a ventilation load or a structural load by query for information associated with “Conference Room.”

Further describing the engineering design system 110, in some embodiments, the automated engineering circuit 114 can initiate the next step in the modeling of the building dataset. The automated engineering circuit 114 can be structured to calculate the building equipment requirements (e.g., total building ventilation load, total building electrical load, etc.) and analyze, collect, determine, and/or access, from the engineering design database 120, a building equipment and equipment infrastructure to support the building equipment. Additionally, in some embodiments, the automated engineering circuit 114 can be configured to analyze, collect, and/or access, from the engineering design database 120, building infrastructure system and equipment install logistics (e.g., financial costs of equipment, labor time and costs, example floor plans, installation time, etc.) and calculate the total engineering installation costs. For example, the automated engineering circuit 114 can determine that a 3 ft×3 ft closet will be required to house a HVAC system required for the project, that it would require three months to order and receive the necessary components for installing the HVAC system, that the time to install the system would take two weeks, and that the total cost to install the system would be $15,000.

In another example, the automated engineering circuit 114 can determine that a different-sized closet is required to house the HVAC system based on a user changing a characteristic of the building itself, such as changing a characteristic of the windows to be double-pane windows instead of single-pane windows. In this example, the automated engineering circuit 114 is configured to recalculate the install logistics and the total engineering installation costs of the HVAC system now required due to the changed characteristic.

Further describing the engineering design system 110, in some embodiments, the data manager 116 can be structured to receive, organize, and store data in the engineering design database 120. In some embodiments, the data manager 116 can be configured to generate various data structures stored in the engineering design database 120. For example, the data manager 116 can be configured to generate data structures for space placement blocks based on the determination of building equipment from the automated engineering circuit 114. The space placement blocks may be a data structure included in the building dataset. The data manager 116 can also be configured to receive or collect a plurality of metadata, e.g., from data sources 160. In some embodiments, the network interface 118 can be structured to facilitate data communication with other computing devices (e.g., user device 140, database provider device 150, etc.) directly or via a network (e.g., network 130, etc.). The network interface 118 may communicate over any of a variety of network protocols, including Ethernet, Bluetooth, WiFi, and the like. As further described below, in some embodiments, the engineering design database 120 can store and associate data containing information about various building properties for use with the components of the engineering design system 110.

In some arrangements, the engineering design database 120 can be configured to include a space type dataset 121, weather dataset 122, equipment dataset 123, geotechnical dataset 124, cost dataset 125, building code dataset 126, and utility dataset 127. In some embodiments, the space type dataset 121 can include data that associates to a functionality or a characteristic of either the building or a building space within the building to a property of either the building or a building space within the building. For example, a room labelled “Conference Room” can be associated to a specific numerical value for ventilation load. In some embodiments, the weather dataset 122 can include data that may associate a location to a climate zone. In some embodiments, the equipment dataset 123 can include data that may associate a piece of equipment to equipment specifications (e.g., weight, electrical load, material type, size, cost, etc.). In some embodiments, the geotechnical dataset 124 can include data that may associate a location to geotechnical information relevant to construction requirements (e.g., seismic zones and earthquake resistant construction requirements, etc.). In some embodiments, the cost dataset 125 can include data that may associate a piece of equipment to labor costs for installing the piece of equipment. In some embodiments, the building code dataset 126 includes data that associates a location to building codes. In some embodiments, the utility dataset 127 can include data that may associate a location to utility information (e.g., electricity costs, water costs, etc.).

Still referring to FIG. 1, in some embodiments, the data used to preset the information in the engineering design database 120 can be retrieved from a data source 160 (e.g., Internet, internal server, hard drives, etc.). In some embodiments, a database provider device 150 may be an interface configured to allow a user or database provider to access and modify the data in the engineering design database 120. In some embodiments, the data manager 116 of the engineering design system 110 can be structured to receive, organize, and store data into the engineering design database 120. In some embodiments, the data manager 116 can receive, organize, and store data at the command of the database provider device 150. In some embodiments, the database provider device 150 may be the same device as the user device 140 (further described below).

Still referring to FIG. 1, in some embodiments, the engineering design system 110 can support the automation of engineering designs and modeling of building infrastructure systems through a user device 140. The user devices 140 could include personal computing devices such as laptops, PDAs, portable media devices, smartphones, tablet computing devices, etc. that may access one or more programs, servers, networks, central computers, etc. In some embodiments, the user devices 140 can communicate with the engineering design system 110 through the network 130. The user devices 140 may execute a software application associated with the engineering design system 110. In some arrangements, the application is executed locally on the user device 140 (e.g., a smartphone application, computing device software application). In some arrangements, the application is accessed on the user device 140 via a website or software application maintained by a server-based computing system or otherwise accessible by the user device 140. Using the application, the user generates a building dataset, inputs a building dataset to automate the engineering designs and logistic calculations of building equipment, and models the building equipment into the inputted building dataset. In some embodiments, the software application can include components of the engineering design system 110 and engineering design database 120.

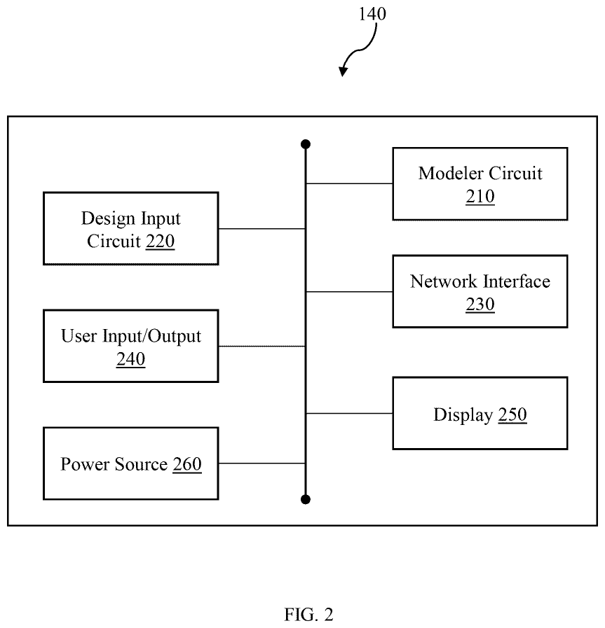

Referring to FIG. 2, a block diagram of the user device 140 is shown according to an example embodiment. As discussed above, the user device 140 may be one or more laptops, PDAs, portable media devices, smartphones, tablet computing devices, etc. In some embodiments, the user device 140 can include a network interface 230. The network interface 230 can be a wireless network interface. In some embodiments, the network interface 230 can include any of a cellular transceiver (e.g., CDMA, GSM, LTE, etc.), a wireless network transceiver (e.g., 802.11X, ZigBee, Bluetooth, etc.), or a combination thereof (e.g., both a cellular transceiver and a Bluetooth transceiver). Additionally, in some embodiments, the network interface 230 can communicate with the engineering design system 110 via the network 130 (e.g., via any combination of the Internet, cellular networks, personal area networks, WiFi networks, etc.).

In some embodiments, the user device 140 can include a display 250 and a user input/output 240. In some arrangements, the display 250 and the user input/output 240 are combined (e.g., as a touchscreen display device). In some arrangements, the display 250 and the user input/output 240 are discrete devices. The user input/output 240 can include any of speakers, keyboards, computer mice, notification LEDs, microphones, biometric sensors (e.g., fingerprint scanners), buttons, switches, cameras, or a combination thereof.

In some embodiments, the user device 140 can include a power source 260. The power source 260 may include grid power, battery power (e.g., alkaline batteries, rechargeable batteries, etc.), and/or another energy source. In arrangements where the power source 260 is a rechargeable battery, the user device 140 also includes circuitry configured to recharge the battery.

In some embodiments, the functionality of the user device 140 described herein is controlled at least in part by the design input circuit 220 and the modeler circuit 210. In some embodiments, both the design input circuit 220 and the modeler circuit 210 are operated at least in part by the software application associated with the engineering design system 110. In some embodiments, the design input circuit 220 can be structured to allow a user of the engineering design system 110 to generate and input a building dataset for transmission of the building dataset to the engineering design system 110. In some embodiments, the modeler circuit 210 can be structured to complete the modeling of the building dataset. Specifically, in some embodiments, the modeler circuit 210 can be structured to allow a user to generate a graphical representation of a building infrastructure system within the graphical representation of a building design and to modify those graphical representations. Additionally, in some embodiments, the design input circuit 220 can send the modified building infrastructure systems and/or building dataset to the engineering design system 110. In some arrangements, information about the logistic calculations (e.g., costs, labor time, etc.) can be displayed on the display 250. In some arrangements, the design input circuit 220 may be integrated into the modeler circuit 210. In some arrangements, the design input circuit 220 or modeler circuit may be incorporated into the engineering design system 110.

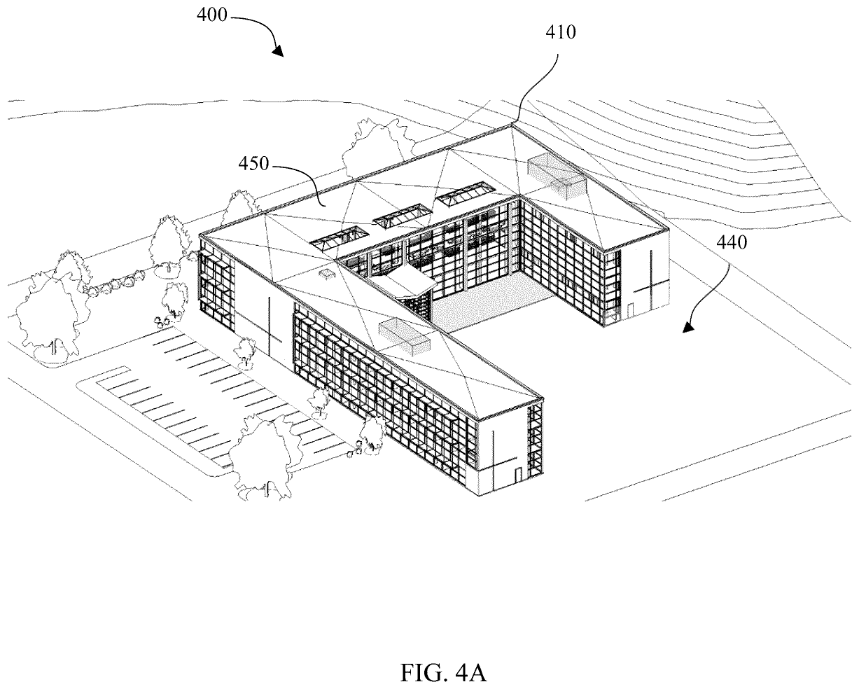

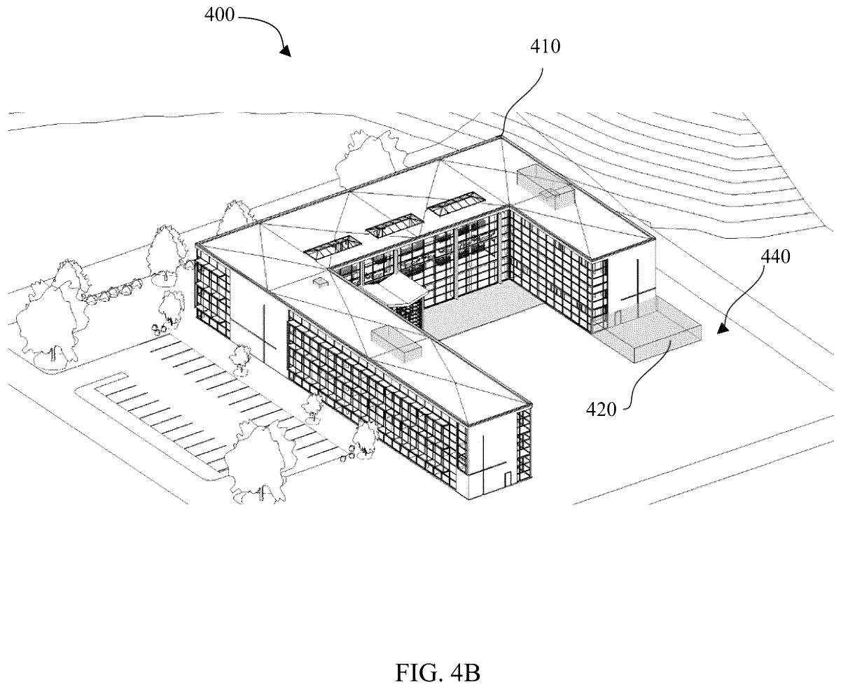

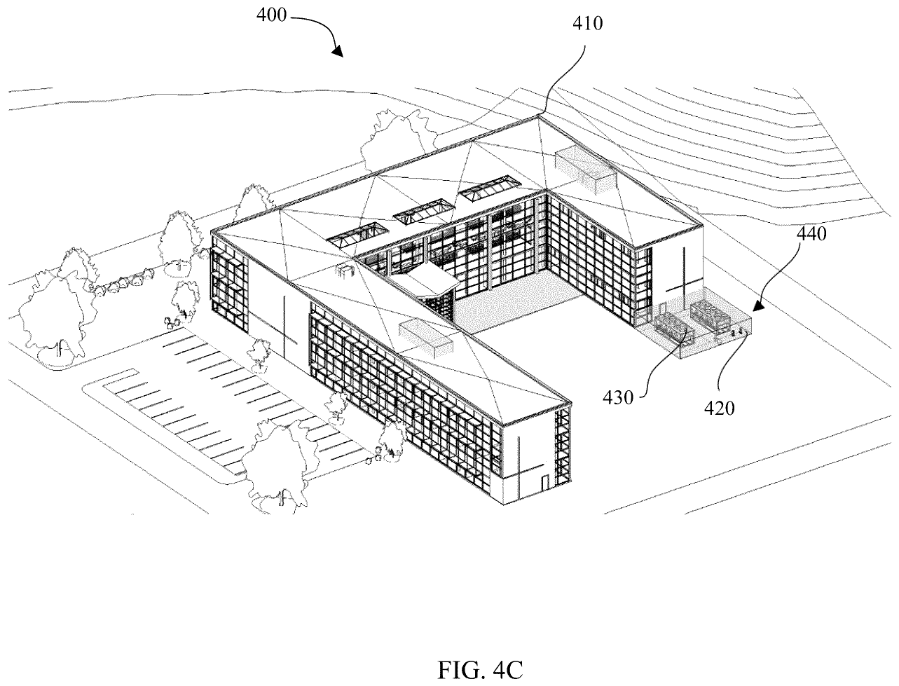

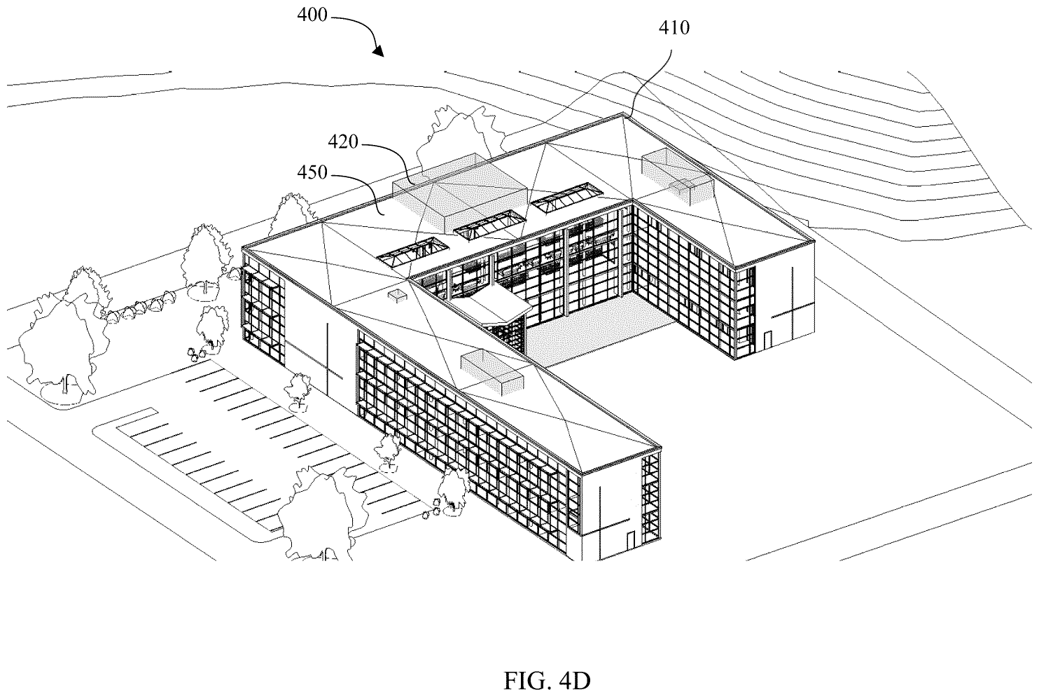

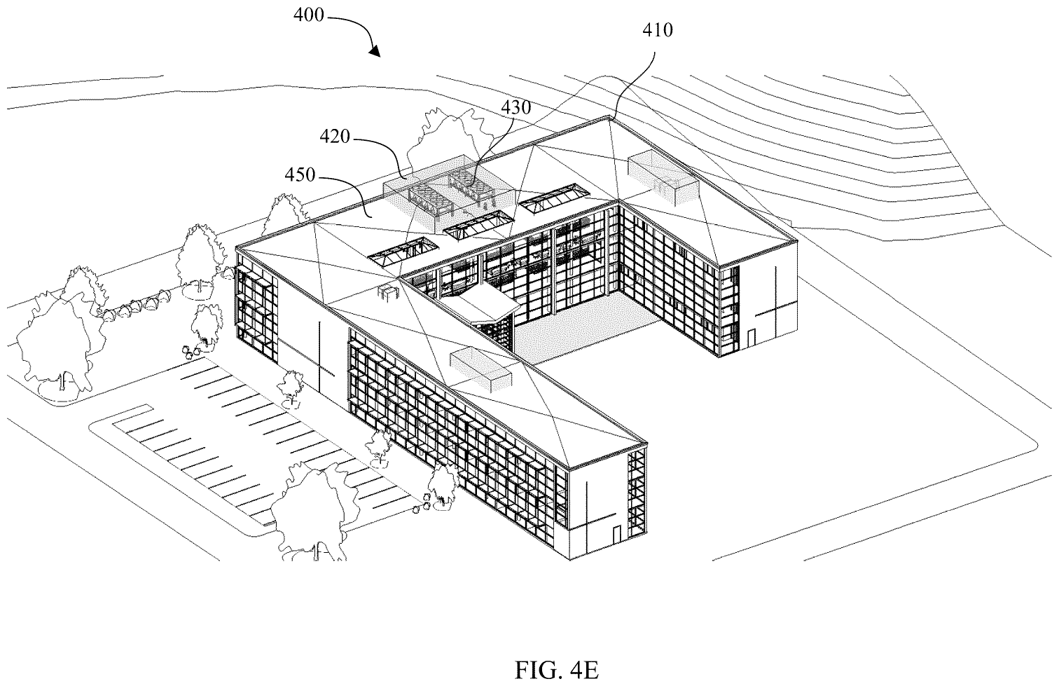

Still referring to FIG. 2, in some embodiments, the modeling of the design input circuit 220 and modeler circuit 210 can include generating graphical representations of the building dataset or building infrastructure system (which may include building equipment and equipment infrastructure) onto the display 250. In some embodiments, to modify the building dataset or building infrastructure system on the display 250, the user can manipulate the graphical representations on the display 250 through use of the user input/output 240. FIG. 4A shows display 400 shown to the user before the user manipulates the graphical representations. In an example, FIGS. 4B and 4C may be an initial display 400 shown to the user of an initial position of the space placement blocks 420, with FIGS. 4D and 4E being modified displays 400 shown to the user after the user manipulates the graphical representations to modify a location of the space placement blocks 420. In some embodiments, the modification of the graphical representations may update the underlying data that encodes the building dataset, building properties, building equipment, or equipment infrastructure. In some embodiments, the design input circuit 220 can send the updated or modified building dataset, building properties, building equipment, or equipment infrastructure to the engineering design system 110 for remodeling of the building dataset, building equipment, or equipment infrastructure. In some embodiments, the remodeling is automatically performed when the user modifies the graphical representations. In some embodiments, the remodeling is performed when the user prompts the remodeling (e.g., clicking a “recalculate” button on the display 250), allowing the user to make multiple modifications before the remodeling occurs.

In some embodiments, the user device 140 can display a plurality of space placement blocks that can offer architects flexibility to tailor building designs according to their preferences or specific requirements. For example, an architect may be working on a commercial building design where the system has automatically placed HVAC units on the rooftop 450 of the building, which is considered the optimal location for efficiency and aesthetics. The graphical representation of these HVAC units is provided as space placement blocks 420 on the interactive building design 410 displayed on the architect's user device 140, as shown in FIGS. 4B-4E. However, for reasons such as unique aesthetic preferences, client requirements, or unique structural constraints, the architect may wish to move the HVAC units or other building equipment from the middle of the rooftop 450 to the side of the building on the ground level 440. Using the interface, the architect can select the space placement blocks 420 and move them to the desired location on the side of the building or to a new location, such as on the rooftop 450 of the building. In some embodiments, the space placement blocks 420 can be modified in size, location, brand, or other characteristics of the HVAC unit or other building equipment. Once the architect has repositioned these space placement blocks 420, the design input circuit 220 sends the updated building design to the engineering design system 110. The engineering design system 110 then proceeds to redetermine, recalculate, and remodel the building design 410 and the building infrastructure system based on this new placement. While this new location might not be the most optimal from the system's initial analysis, the engineering design system 110 can optimize the building design and building infrastructure system within this new constraint, possibly adjusting ductwork, electrical systems, and other associated elements to best suit the new location of the HVAC units or other building equipment. For example, in the initial modelling of HVAC units, the engineering design system 110 could determine that an HVAC unit located on the rooftop 450 of the building and 500 ft of ductwork is most optimal. The architect could then change the location of the HVAC unit to the side of the building on the ground level 440. Based on that change in location, the engineering design system 110 could determine that 700 ft of ductwork is needed to support the new location.

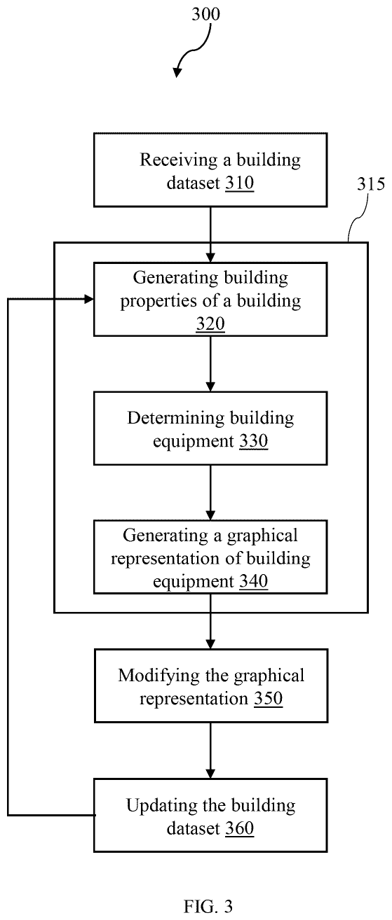

Referring to FIG. 3, a flow diagram of a method of automatically producing an engineering design based on a building dataset is shown according to an example embodiment. The flow diagram details the interaction between the user device 140 and the engineering design system 110.

In a broad overview of method 300, at block 310, a user can input a building dataset via the design input circuit 220 and the building and space interpreter circuit 112 can receive the building dataset. At block 315, components of a user device 140 and/or engineering design system 110 can model the building dataset. At block 320, the initial step of modeling the building dataset can include the building and space interpreter circuit 112 generating building properties. At block 330, the next step of modeling the building dataset can include the automated engineering circuit 114 determining building equipment. At block 340, the final step of modeling the building dataset can include the modeler circuit 210 generating a graphical representation of the building equipment. At block 350, a user can modify the graphical representation of the building equipment. At block 360, in response to the modification, the user device could update the building dataset to encode the modification of the graphical representation of the building equipment. Additional, fewer, or different operations may be performed depending on the particular embodiment. In some embodiments, some, or all operations of method 300 may be performed by one or more circuits executing on one or more computing devices, systems, or servers. In various embodiments, each operation may be re-ordered, added, removed, or repeated. In some arrangements, blocks can be optionally executed by the one or more processing circuits.

At block 310, a user can input a building dataset via the design input circuit 220 and a building and space interpreter circuit 112 can receive the building dataset. In some embodiments, a user inputs and transmits, via a design input circuit 220 of the user device 140, a building dataset to the building and space interpreter circuit 112 of the engineering design system 110. In such embodiment, the building dataset includes the building design and metadata with information about the building design. In such embodiment, the building dataset can include floor plans, geographic location of the building, thermal properties of the building materials, type of building (e.g., apartments, offices, etc.), functionality of spaces in the building (e.g., break room, conference room, restrooms, etc.), and other characteristics of the building or planned use of the building. In some embodiments, the user device 140 connects to the engineering design system 110 through a network 130. In some embodiments, the engineering design system 110 is integrated into a software application installed on the user device 140. For example, an architect user could input, via the design input circuit 220 of the user device 140, an architectural drawing of a second story building with metadata that includes information that the building is located in Columbus, Ohio and that a building space is labelled “Offices.”

At block 315, components of a user device 140 and/or engineering design system 110 can model the building dataset. In some embodiments, the modeling step could include block 320 (generating properties of a building), block 330 (determining building equipment), and block 340 (generating a graphical representation of building equipment). Additional or fewer operations could be involved in this step. Various devices can operate these steps in a number of combinations. These steps are described in further detail below.

At block 320, the initial step of the modeling could include the building and space interpreter circuit 112 generating building properties (e.g., thermal properties, ventilation load, electrical load, etc.) based on the building dataset. To generate the building properties, the building and space interpreter circuit 112 can analyze, collect, and/or access the building properties from an engineering design database 120. The engineering design database can include preset datasets that associate data in the building dataset to building properties. The building and space interpreter circuit 112 can transmit the building properties to the automated engineering circuit 114 of the engineering design system 110. For example, the building and space interpreter circuit 112 could identify that information needed to model the building dataset is missing from the building dataset. In such example, the building and space interpreter circuit 112 could query the weather dataset 122 for the climate zone of Columbus; the geotechnical dataset 124 for seismic data of Columbus; and the building code dataset 126 for the local building ordinances. Additionally, the space interpreter circuit 112 could query the space type dataset for the number of outlets, amount of HVAC ducts, or expected building space temperature associated with an “Office” building space type. The generated information could be specific to the building space type. For example, a query based on a “Apartment” building space type could generate a different number of outlets, amount of HVAC ducts, or expected building space temperature than the “Office” building space type.

At block 330, the next step of the modeling could include the automated engineering circuit 114 determining the building equipment (e.g., HVAC unit, circuit breaker, water tanks, etc.) based on the building dataset and building properties. To determine the building equipment, the automated engineering circuit 114 can analyze, collect, and/or access building equipment from the engineering design database 120 based on building equipment specifications that support the building properties. In some embodiments, the automated engineering circuit 114 additionally can analyze, collect, and/or access equipment infrastructure (e.g., electrical conduits, plumbing, structural beams, etc.) from the engineering design database 120 based on the building equipment specifications that support the building equipment. In some embodiments, the automated engineering circuit 114 can calculate the logistics (e.g., floor plan, install time, cost, etc.) that support the building equipment and equipment infrastructure. The automated engineering circuit 114 can transmit data about the building properties, building equipment, equipment infrastructure, and logistics to the modeler circuit 210 of the user device 140. For example, the automated engineering circuit 114 could calculate the total building heat load based on the climate zone, local building ordinances (e.g., thermal properties of building materials, HVAC codes, etc.), HVAC ducts, and building space temperature. Additionally, the automated engineering circuit 114 could determine that a specific HVAC system would be able to meet the building heat load. The automated engineering circuit 114 could determine that the HVAC system would require a 5 ft×5 ft floor plan with 480V electricity. Additionally, the automated engineering circuit 114 could determine the conduits and HVAC ducts that would be needed for the HVAC system. The automated engineering circuit 114 could then determine the location of and design of the HVAC system and HVAC infrastructure in the architectural drawing. The automated engineering circuit 114 could query the cost dataset 125 and utility dataset 127 for the information needed to calculate the labor costs, delivery time, and installation time of the HVAC system and HVAC infrastructure.

At block 340, the final step of the modeling includes the modeler circuit 210 generating, in a graphical representation of the building design 410, a space placement block 420 of the building equipment. In some embodiments. the space placement block 420 could be an interactive graphical representation of the building equipment that is modifiable within the graphical representation of the building design 410. The user device 140 could generate the graphical representations onto the display 250 of the user device 140. In some embodiments, the modeler circuit 210 additionally could generate a space placement block of the equipment infrastructure. In some embodiments, the user device 140 can display the building properties or logistics on the display 250. For example, the modeler circuit 210 could generate a space placement block 420 of the HVAC system and another space placement block of the HVAC infrastructure. The modeler circuit 210 could generate those space placement blocks on the architectural drawing shown on the display 250 of the user device 140. Additionally, the modeler circuit 210 can display the costs and delivery time of the HVAC system and HVAC infrastructure on the display 250. In some embodiments, the engineering design system 110 includes the modeler circuit 210 and the engineering design system 110 would perform the final step of the modeling. An example display of an initial modeled building dataset and space placement blocks is shown in FIGS. 4B and 4C.

At block 350, the user can modify the space placement block 420 of the building equipment on the display 250 by use of a user input/output 240, such as a keyboard, touch screen, or computer mouse. In some embodiments, the user can modify the graphical representations of the building dataset or building equipment. In some embodiments, the user modifies the building properties or logistics. For example, the user can move the computer mouse to change the location of the space placement block of the HVAC system on the graphical representation of the architectural drawing. Additionally, the user could select a different brand of HVAC system than the brand of HVAC system shown on the graphical representation. An example display of a modified space placement block in a modelled building dataset is shown in FIGS. 4D and 4E.

At block 360, the user device 140 can update the building dataset to encode the modification of the space placement block into the building dataset. The design input circuit 220 can transmit the updated building dataset to the building and space interpreter circuit 112 of the engineering design system 110 to remodel the updated building dataset (block 315). In some embodiments, the user device 140 can update the building properties, building equipment, building infrastructure system, or logistics. In some embodiments, the user device updates the building dataset in response to the modification of the graphical representation of the building design or building infrastructure system. In some embodiments, the user device updates the building dataset in response to the modification of the building properties or logistics. In some embodiments, design input circuit 220 can transmit the updated building properties, building equipment, building infrastructure system, or logistics to the building and space interpreter circuit 112 of the engineering design system 110 to generate updated graphical representations. For example, the user device 140 can update the building dataset when the space placement block of the HVAC system is moved or otherwise altered. Additionally, the user device 140 can update the building equipment when the user selects a different brand of HVAC system. The updated building dataset and building equipment could be transmitted to the building and space interpreter circuit 112 to initiate the remodeling.

Referring to FIG. 4A in more detail, a display 400 of a graphical representation of a building design 410 displayed on the user device 140 is shown according to an example embodiment. As shown, while this example does include space placement blocks on the rooftop 450 of the building, the figure omits the space placement blocks 420 depicting the building equipment, such components of an HVAC system, as described above. In some embodiments, this display 400 is an initial display that is displayed on the user device 140 before a user specifies the need for certain equipment that will later be depicted in space placement blocks 420 that are added to the display 400 later on.

Referring to FIG. 4B in more detail, a display 400 of a graphical representation of a building design 410 displayed on the user device 140 depicting a space placement block 420 of a HVAC unit on a ground level 440 is shown according to an example embodiment. In this example, space placement blocks 420 have been generated and displayed on the display 400. As shown, the space placement blocks 420 are shown as being located on a ground level 440 with respect to the building. In some embodiments, the space placement blocks 420 are generated and displayed on the ground level 440 of the building based on a user input requiring the associated building equipment depicted by the space placement blocks 420 to be located on the ground level 440. In some embodiments, the space placement blocks 420 are generated and displayed on the ground level 440 of the building automatically by the engineering design system 110 based on a design characteristic, a cost comparison of locating the associated building equipment elsewhere respective of the building (e.g., on a rooftop 450 of the building), an environmental factor, a regulation factor, or other factor.

Referring to FIG. 4C in more detail, a display 400 of a graphical representation of a building design 410 displayed on the user device 140 depicting the space placement block 420 of the HVAC unit on the ground level with building equipment 430 is shown according to an example embodiment. In some embodiments, the engineering design system 110 is configured to generate building equipment 430 to be displayed within the space placement blocks 420. The building equipment 430 may be automatically generated and displayed within the space placement blocks 420 upon generation of the space placement blocks 420, or toggled to be displayed or not displayed based on a user's preference. In some embodiments, specific building equipment 430 is displayed based on an equipment selection made by the user. For example, based on a user selecting a specific HVAC condenser model manufactured by a specific manufacturer, the building equipment 430 displayed in the space placement blocks 420 may represent this specific HVAC condenser model. In some embodiments, the engineering design system 110 selects specific equipment (e.g., a specific model from a specific manufacturer) based on a design characteristic, a cost comparison of the specific model with other specific models from the engineering design database,), an environmental factor, a regulation factor, or other factor.

Referring to FIG. 4D in more detail, a display 400 of a graphical representation of a building design 410 displayed on the user device 140 depicting a space placement block 420 of the HVAC unit on a rooftop 450 is shown according to an example embodiment. In this example, space placement blocks 420 have been generated and displayed on the display 400. As shown, the space placement blocks 420 are shown as being located on a rooftop 450 of the building. In some embodiments, the space placement blocks 420 are generated and displayed on the rooftop 450 of the building based on a user input requiring the associated building equipment depicted by the space placement blocks 420 to be located on the rooftop 450. In some embodiments, the space placement blocks 420 are generated and displayed on the rooftop 450 of the building automatically by the engineering design system 110 based on a design characteristic, a cost comparison of locating the associated building equipment elsewhere respective of the building (e.g., on the ground level 440 respective of the building), an environmental factor, a regulation factor, or other factor.

Referring to FIG. 4E in more detail, a display 400 of a graphical representation of a building design 410 displayed on the user device 140 depicting the space placement block 420 of the HVAC unit on the rooftop 450 with building equipment 430 is shown according to an example embodiment. The space placement blocks 420 and building equipment 430 shown in FIG. 4E may have the same or similar function as the space placement blocks 420 and building equipment 430 as discussed with respect to FIG. 4C.

As discussed above, in some examples, the space placement blocks 420 are changed from being displayed in a first position (e.g., the ground level 440) to be displayed in a second position (e.g., the rooftop 450) based on a user input to modify the placement of the space placement blocks 420. In some embodiments, the space placement blocks 420 are changed from being displayed in the second position (e.g., the rooftop 450) to be displayed in the first position (e.g., the ground level 440) based on a user input to modify the placement of the space placement blocks 420. In some embodiments, the engineering design system 110 moves the space placement blocks 440 but keeps the space placement blocks on the same level of the building. For example, the engineering design system 110 can move the space placement blocks from a first position on the rooftop 450 (e.g., closer to an eastern portion of the rooftop 450) to a second position on the rooftop 450 (e.g., closer to a western portion of the rooftop 450). In some embodiments, the space placement blocks 420 can be directly modified by the user to take a different shape, be a different size, or to be located in a different position. In some embodiment, the space placement blocks 420 are inserted randomly into the building design 410 or at a set location in the building design 410 (e.g., a center point of the building design 410, the center point of a room, against a wall of the building design 410, outside the building design 410), and requires the user to relocate the space placement blocks 420 to a desired location (e.g., by selecting the space placement blocks 420 to input a new location or to drag-and-drop the space placement blocks).

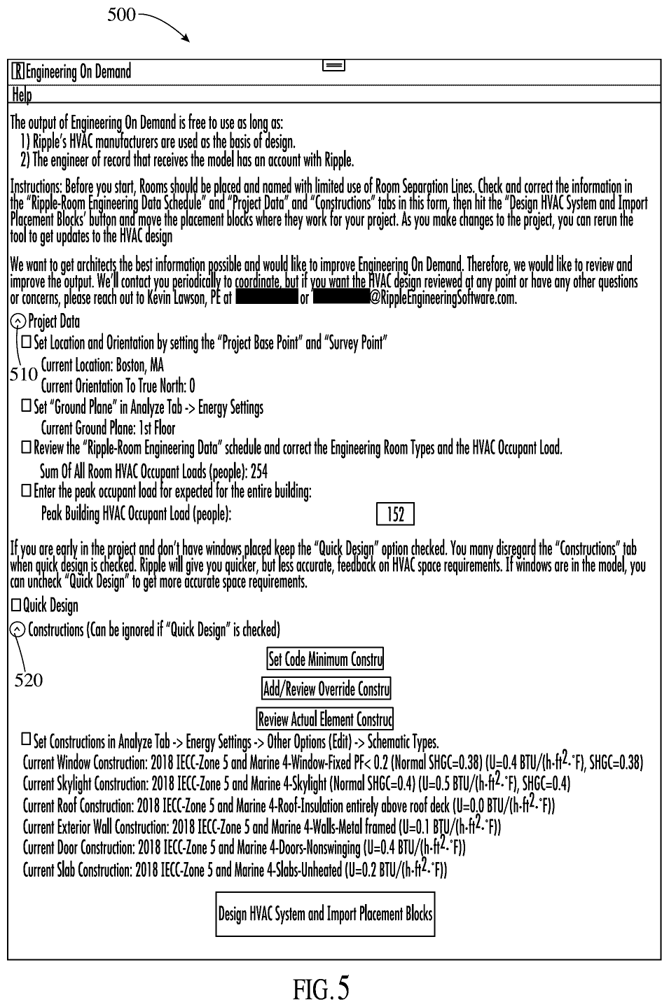

Referring to FIG. 5, a display 500 of an interactive user interface on the user device 140 to enable the user to configure the engineering design system 110 is shown according to an example embodiment. In some embodiments, the interactive user interface may be displayed when the engineering design system 110 is initiated. As shown, the interactive user interface includes a project data tab 510 and a constructions tab 520, as well as a plurality of selectable sub-options and settings that are selectable (e.g., via check boxes, buttons, or other indicia). The projects data tab 510 can include settings to enable the user to set the location (e.g., a city and state) and orientation (e.g., how many degrees to true north) of the building design 410, to set a ground plane of the building design 410 (e.g., to indicate the entry level is the first floor), to set a capacity level (e.g., a sum of all room HVAC occupant loads) for the building design 410, and to enter a peak occupant load for the building design. The constructions tab 520 can include settings to enable the user to set code minimum constructions, add or review override constructions, or to review actual element constructions associated with the building design 410. For example, the option to add or review override constructions may enable a user to add settings or override current settings for certain construction materials, such as wall properties (e.g., changing exterior walls to be Air Frame, metal-framed walls having an insulation R-value of 13+7.5 continuous insulation, among other options. In some embodiments, the engineering design system 110 is configured to use default settings for both the project data tab 510 options and the constructions tab 520 options (e.g., a peak occupant load may automatically be set at 60 percent of the capacity level). In some embodiments, the project data tab 510 options and the constructions tab 520 options can be dictated by a third party, such as architect.

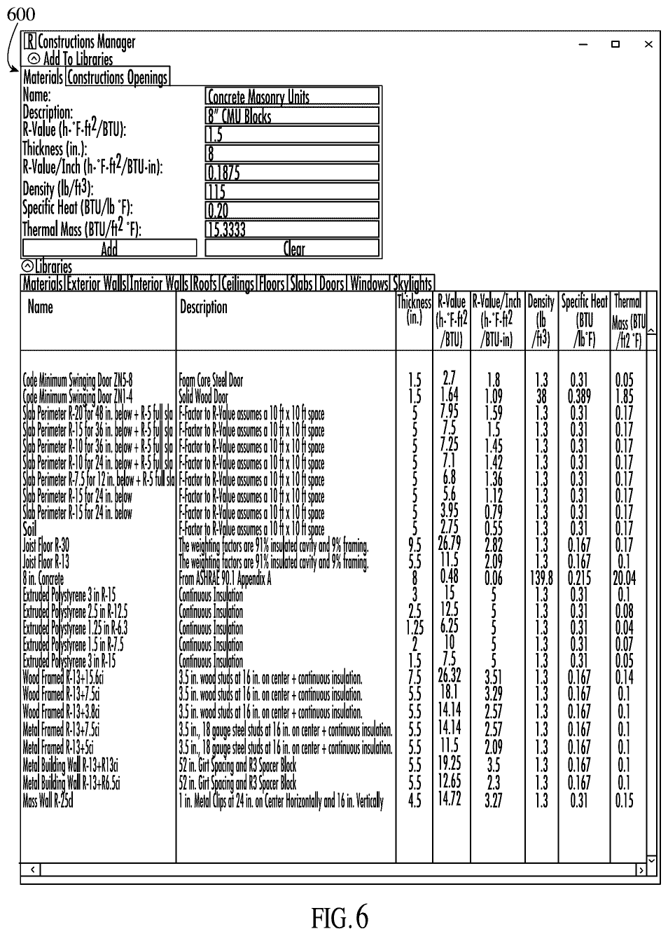

Referring to FIG. 6, a display 600 of an interactive user interface on the user device 140 to enable the user to select building materials for components of the building design 410 is shown according to an example embodiment. In some embodiments, the user is able to select a specific construction element of the building design 410 (e.g., by selecting a specific wall, window, door, or other component) to change a property. As shown in FIG. 6, the user is able to select a material for a wall from among a list of available materials, such as ceramic tile, cherry, concrete masonry units, etc. Upon selecting a specific material from among the list, the user can edit the material properties of the specific material (e.g., behavior, thermal conductivity, specific heat, density, emissivity, permeability, porosity, reflectivity, electrical resistivity, etc.).

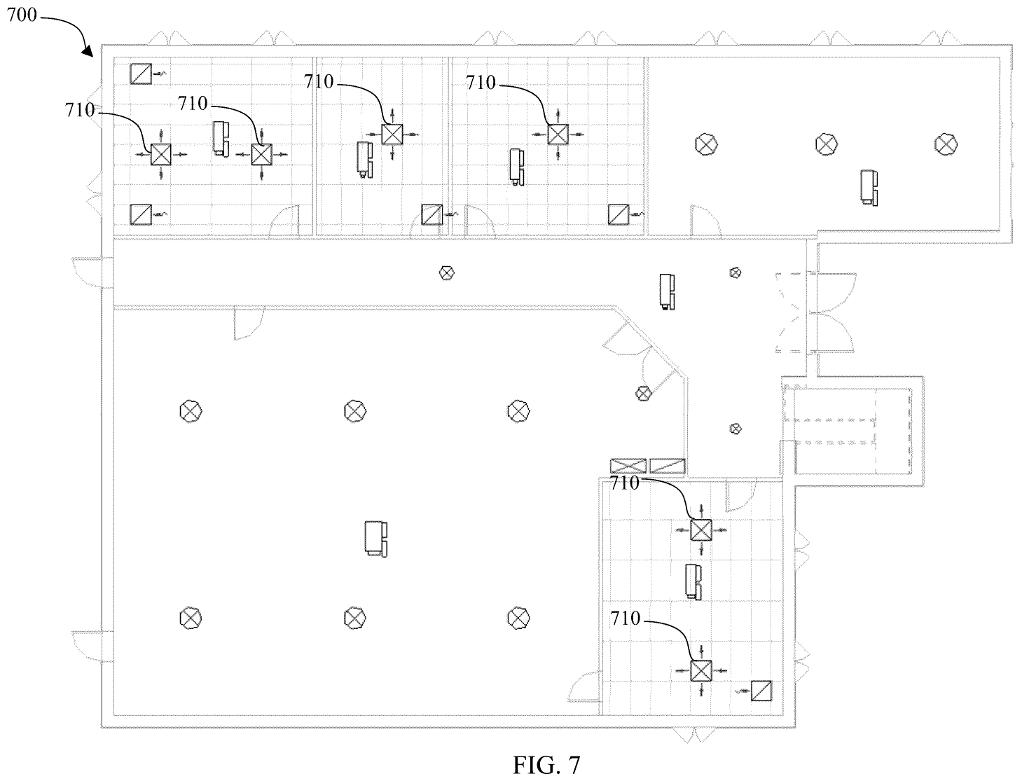

Referring to FIG. 7, a display 700 of an interactive user interface of the user device 140 displaying a mechanical model associated with the building design 410 is shown according to an example embodiment. The mechanical model may be automatically generated by the engineering design system 110, or based on a user selection. The mechanical model provides a schematic of the building design 410 on a floor-by-floor or room-by-room basis. The mechanical model may include a variety of calculated information, such as a load calculation report, equipment selected, and a layout of diffusers 710 for the HVAC system distributed throughout the building design 410. The information and various components displayed via the mechanical model are dictated by the characteristics of the building design 410, including the placement of the space placement blocks 420.

The embodiments described herein have been described with reference to drawings. The drawings illustrate certain details of specific embodiments that implement the systems, methods and programs described herein. However, describing the embodiments with drawings should not be construed as imposing on the disclosure any limitations that may be present in the drawings.

It should be understood that no claim element herein is to be construed under the provisions of 35 U.S.C. § 112 (f), unless the element is expressly recited using the phrase “means for.”

As used herein, the term “circuit” may include hardware structured to execute the functions described herein. In some embodiments, each respective “circuit” may include machine-readable media for configuring the hardware to execute the functions described herein. The circuit may be embodied as one or more circuitry components including, but not limited to, processing circuitry, network interfaces, peripheral devices, input devices, output devices, sensors, etc. In some embodiments, a circuit may take the form of one or more analog circuits, electronic circuits (e.g., integrated circuits (IC), discrete circuits, system on a chip (SOCs) circuits, etc.), telecommunication circuits, hybrid circuits, and any other type of “circuit.” In this regard, the “circuit” may include any type of component for accomplishing or facilitating achievement of the operations described herein. For example, a circuit as described herein may include one or more transistors, logic gates (e.g., NAND, AND, NOR, OR, XOR, NOT, XNOR, etc.), resistors, multiplexers, registers, capacitors, inductors, diodes, wiring, and so on.

A “circuit” may also include one or more processors communicatively coupled to one or more memory or memory devices. In this regard, the one or more processors may execute instructions stored in the memory or may execute instructions otherwise accessible to the one or more processors. In some embodiments, the one or more processors may be embodied in various ways. The one or more processors may be constructed in a manner sufficient to perform at least the operations described herein. In some embodiments, the one or more processors may be shared by multiple circuits (e.g., circuit A and circuit B may comprise or otherwise share the same processor which, in some example embodiments, may execute instructions stored, or otherwise accessed, via different areas of memory). Alternatively or additionally, the one or more processors may be structured to perform or otherwise execute certain operations independent of one or more co-processors. In other example embodiments, two or more processors may be coupled via a bus to enable independent, parallel, pipelined, or multi-threaded instruction execution. Each processor may be implemented as one or more general-purpose processors, application specific integrated circuits (ASICs), field programmable gate arrays (FPGAs), digital signal processors (DSPs), or other suitable electronic data processing components structured to execute instructions provided by memory. The one or more processors may take the form of a single core processor, multi-core processor (e.g., a dual core processor, triple core processor, quad core processor, etc.), microprocessor, etc. In some embodiments, the one or more processors may be external to the apparatus, for example the one or more processors may be a remote processor (e.g., a cloud based processor). Alternatively or additionally, the one or more processors may be internal and/or local to the apparatus. In this regard, a given circuit or components thereof may be disposed locally (e.g., as part of a local server, a local computing system, etc.) or remotely (e.g., as part of a remote server such as a cloud-based server). To that end, a “circuit” as described herein may include components that are distributed across one or more locations.

An example system for implementing the overall system or portions of the embodiments might include a general purpose computing computers in the form of computers, including a processing unit, a system memory, and a system bus that couples various system components including the system memory to the processing unit. Each memory device may include non-transient volatile storage media, non-volatile storage media, non-transitory storage media (e.g., one or more volatile and/or non-volatile memories), etc. In some embodiments, the non-volatile media may take the form of ROM, flash memory (e.g., flash memory such as NAND, 3D NAND, NOR, 3D NOR, etc.), EEPROM, MRAM, magnetic storage, hard discs, optical discs, etc. In other embodiments, the volatile storage media may take the form of RAM, TRAM, ZRAM, etc. Combinations of the above are also included within the scope of machine-readable media. In this regard, machine-executable instructions comprise, for example, instructions and data which cause a general purpose computer, special purpose computer, or special purpose processing machines to perform a certain function or group of functions. Each respective memory device may be operable to maintain or otherwise store information relating to the operations performed by one or more associated circuits, including processor instructions and related data (e.g., database components, object code components, script components, etc.), in accordance with the example embodiments described herein.

It should also be noted that the term “input devices,” as described herein, may include any type of input device including, but not limited to, a keyboard, a keypad, a mouse, joystick or other input devices performing a similar function. Comparatively, the term “output device,” as described herein, may include any type of output device including, but not limited to, a computer monitor, printer, facsimile machine, or other output devices performing a similar function.

It should be noted that although the diagrams herein may show a specific order and composition of method steps, it is understood that the order of these steps may differ from what is depicted. For example, two or more steps may be performed concurrently or with partial concurrence. Also, some method steps that are performed as discrete steps may be combined, steps being performed as a combined step may be separated into discrete steps, the sequence of certain processes may be reversed or otherwise varied, and the nature or number of discrete processes may be altered or varied. The order or sequence of any element or apparatus may be varied or substituted according to alternative embodiments. Accordingly, all such modifications are intended to be included within the scope of the present disclosure as defined in the appended claims. Such variations will depend on the machine-readable media and hardware systems chosen and on designer choice. It is understood that all such variations are within the scope of the disclosure. Likewise, software and web implementations of the present disclosure could be accomplished with standard programming techniques with rule based logic and other logic to accomplish the various database searching steps, correlation steps, comparison steps and decision steps.

The foregoing description of embodiments has been presented for purposes of illustration and description. It is not intended to be exhaustive or to limit the disclosure to the precise form disclosed, and modifications and variations are possible in light of the above teachings or may be acquired from this disclosure. The embodiments were chosen and described in order to explain the principals of the disclosure and its practical application to enable one skilled in the art to utilize the various embodiments and with various modifications as are suited to the particular use contemplated. Other substitutions, modifications, changes and omissions may be made in the design, operating conditions and arrangement of the embodiments without departing from the scope of the present disclosure as expressed in the appended claims.

What is claimed is:

1. A system comprising;
one or more processing circuits and memory storing instructions which, when executed, cause the one or more processing circuits to:
receive a building dataset comprising an architectural drawing of a building and metadata;
model the building dataset by:
generating building properties of a building space based on the building dataset;
determining building equipment based on the building properties and the building dataset; and
generating, in a graphical representation of the building displayed on a user device, a space placement block of the building equipment, wherein the space placement block is an interactive graphical representation of the building equipment that is modifiable within the graphical representation of the building; and
remodel, based on a modification of the space placement block, the building dataset by updating at least one of the building properties or building equipment to encode the modification of the space placement block into the building dataset.

2. The system of claim 1, wherein the metadata comprises information corresponding to a functionality or a characteristic of either the building or the building space within the building, and wherein the modeling determines spatial relationships between the building equipment and other components within the building space based on the metadata.

3. The system of claim 1, wherein generating the building properties of the building space based on the metadata of the building dataset comprises retrieving the building properties from a space type dataset, wherein the space type dataset associates the metadata to the building properties.

4. The system of claim 1, wherein determining the building equipment based on the building properties and the metadata comprises calculating a ventilation load of the building by retrieving ventilation load variables based on the building properties and the metadata.

5. The system of claim 1, wherein determining the building equipment based on the building properties and the metadata further comprises determining equipment infrastructure to support the building equipment, and wherein an equipment infrastructure determination is based on both a physical and an operational need of the building equipment.

6. The system of claim 5, wherein generating, in the graphical representation of the building, the space placement block of the building equipment further includes generating a second graphical representation of the equipment infrastructure in the graphical representation of the building.

7. The method of claim 1, wherein the building dataset is remodeled by updating at least one of the building properties or the building equipment to encode the modification of the space placement block into the building dataset comprises prompting a user to select a new building equipment from an equipment dataset.

8. A method comprising:
receiving a building dataset comprising an architectural drawing of a building and metadata;
modeling the building dataset by:
generating building properties of a building space based on the building dataset;
determining building equipment based on the building properties and the building dataset; and
generating, in a graphical representation of the building displayed on a user device, a space placement block of the building equipment, wherein the space placement block is an interactive graphical representation of the building equipment that is modifiable within the graphical representation of the building; and
remodeling, based on a modification of the space placement block, the building dataset by updating at least one of the building properties or building equipment to encode the modification of the space placement block into the building dataset.

9. The method of claim 8, wherein the metadata comprises information corresponding to a functionality or a characteristic of either the building or the building space within the building, and wherein the modeling determines spatial relationships between the building equipment and other components within the building space based on the metadata.

10. The method of claim 8, wherein generating the building properties of the building space based on the metadata of the building dataset comprises retrieving the building properties from a space type dataset, wherein the space type dataset associates the metadata to the building properties.

11. The method of claim 8, wherein determining the building equipment based on the building properties and the metadata comprises calculating a ventilation load of the building by retrieving ventilation load variables based on the building properties and the metadata.

12. The method of claim 8, wherein determining the building equipment based on the building properties and the metadata further comprises determining equipment infrastructure to support the building equipment, and wherein an equipment infrastructure determination is based on both a physical and an operational need of the building equipment.

13. The method of claim 12, wherein generating, in the graphical representation of the building, the space placement block of the building equipment further includes generating a second graphical representation of the equipment infrastructure in the graphical representation of the building.

14. The method of claim 8, wherein remodeling the building dataset by updating at least one of the building properties or the building equipment to encode the modification of the space placement block into the building dataset comprises prompting a user to select a new building equipment from an equipment dataset.

15. A method comprising:
receiving a building dataset comprising an architectural drawing of a building and space type data that represents a space type;
modeling the building dataset by:
generating space properties data to the building dataset based on the space type of a building space within the building, wherein the space properties data is retrieved from a space type dataset that comprises a plurality of space type data and a plurality of space properties data associated to each space type;
determining a HVAC system and HVAC infrastructure from an equipment dataset, wherein the equipment dataset comprises a plurality of HVAC systems and a plurality of HVAC infrastructures; and
generating, in a graphical representation of the architectural drawing, a space placement block of the HVAC system and the HVAC infrastructure, wherein the space placement block is an interactive graphical representation of the HVAC system and the HVAC infrastructure that is modifiable within the graphical representation of the architectural drawing; and
remodeling, based on a modification of the space placement block, the building dataset by updating at least one of the space properties data, the HVAC system, or the HVAC infrastructure to encode the modification of the space placement block into the building dataset.

16. The method of claim 15, wherein determining a HVAC system and HVAC infrastructure from an equipment dataset further comprises determining HVAC infrastructure to support the HVAC system.

17. The method of claim 16, wherein the HVAC infrastructure determination is based on at least one of a physical need or an operational need of the building equipment.

18. The method of claim 16, wherein the graphical representation is a first graphical representation, and wherein modeling the building dataset further comprises generating a second graphical representation of the HVAC infrastructure in the graphical representation of the building.

19. The method of claim 15, wherein remodeling the building dataset is based on an input to cause the space placement block of the HVAC system to at least one of be resized or to be moved to a different location of the building.

20. The method of claim 15, wherein remodeling the building dataset comprises prompting a user to select a new building equipment from an equipment dataset.
